(19) United States
(12) Patent Application Publication
(10) Pub. No.: US 2008/0315926 A1
(43) Pub. Date: Dec. 25, 2008

(54) Frequency Synthesizer

(76) Inventor: Min Jong Yoo, Bucheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/143,987

(22) Filed: Jun. 23, 2008

(30) Foreign Application Priority Data
Jun. 25, 2007 (KR) 10-2007-0062508

(51) Int. Cl. H03L 7/06

(52) U.S. Cl. 327/157

(57) ABSTRACT

Disclosed is a frequency synthesizer. The frequency synthesizer includes a phase frequency detector for generating an up signal and a down signal by detecting frequency and phase differences between a reference signal and a comparison signal, a charge pump for outputting a control signal according to the up signal and the down signal, a voltage controlled oscillator for outputting an oscillation output signal according to the control signal, a duty cycle correction circuit connected with the voltage controlled oscillator to compensate for a duty cycle of the oscillation output signal, and a feedback divider for providing the comparison signal to the phase frequency detector by dividing a frequency of the oscillation output signal.

### CROSS-REFERENCE TO RELATED APPLICATION

The application claims priority under 35 U.S.C. §119(e) of Korean Patent Application No. 10-2007-0062508, filed on Jun. 25, 2007, which is hereby incorporated by reference in its entirety.

### BACKGROUND

A large scale integrated circuit apparatus having a microprocessor has been developed. Typically, in the microprocessor, an operating apparatus that executes an operation indicated by a program may operate in synchronization with a clock.

To generate the clock, a frequency synthesizer circuit using a PLL (phase locked loop) is often used.

However, because phase noise of the PLL directly exerts influence upon a system, it is very important to design a frequency synthesizer having low jitter.

Thus, there exists a need in the art for an improved frequency synthesizer.

### BRIEF SUMMARY

Embodiments of the present invention provide a frequency synthesizer.

According to an embodiment of the present invention, a frequency synthesizer is provided having low jitter components.

In addition, an embodiment can provide a frequency synthesizer capable of minimizing power consumption.

A frequency synthesizer according to one embodiment includes a phase frequency detector for generating an up signal and a down signal based on a detected frequency difference and phase difference between a reference signal and a comparison signal; a charge pump for outputting a control signal by charging or discharging voltage according to the up signal or the down signal; a voltage controlled oscillator for outputting a signal having a frequency as an oscillation output signal according to the control signal output from the charge pump; a duty cycle correction circuit connected with the voltage controlled oscillator to compensate for a duty cycle; and a feedback divider for providing the comparison signal to the phase frequency detector by dividing a frequency of the oscillation output signal.

### BRIEF DESCRIPTION OF THE DRAWINGS

FIG. 1 is a block diagram illustrating a frequency synthesizer according to an embodiment of the present invention.

FIG. 2 is a circuit diagram illustrating a phase frequency detector according to an embodiment of the present invention.

FIG. 3 is a circuit diagram illustrating a charge pump of a frequency synthesizer according to an embodiment of the present invention.

FIG. 4 is a circuit diagram illustrating a voltage controlled oscillator of a frequency synthesizer according to an embodiment of the present invention.

FIG. 5 is a circuit diagram illustrating a duty cycle correction circuit of a frequency synthesizer according to an embodiment of the present invention.

### DETAILED DESCRIPTION

Hereinafter, a frequency synthesizer according to an embodiment will be described with reference to the accompanying drawings.

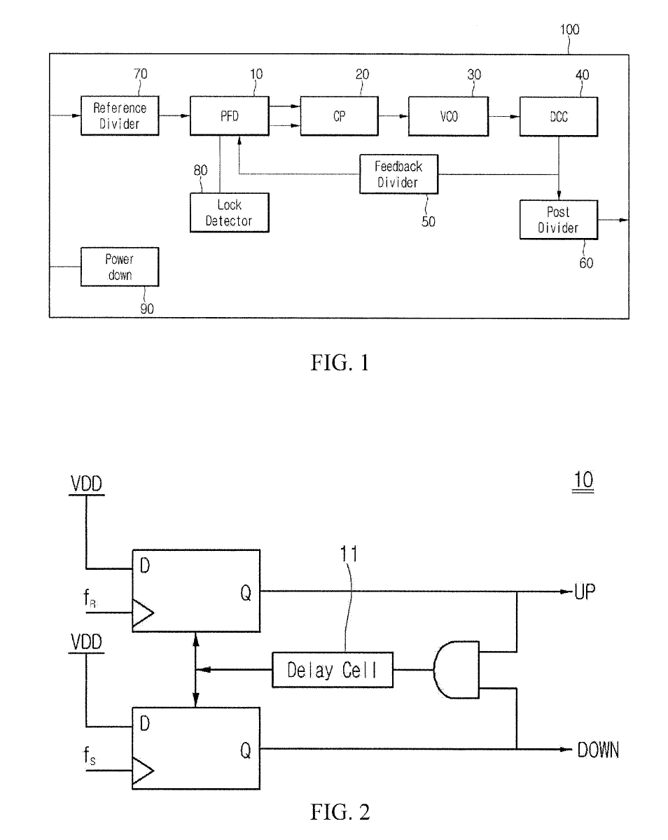

FIG. 1 is a block diagram illustrating a frequency synthesizer according to an embodiment.

According to an embodiment, the subject frequency synthesizer 100 can be suitable for obtaining 650 MHz output frequency characteristic.

Referring to FIG. 1, the frequency synthesizer 100 can include a phase frequency detector (PFD) 10, a charge pump (CP) 20, a voltage controlled oscillator (VCO) 30, a duty correction circuit (DCC) 40, and a feedback divider 50.

In a further embodiment, the frequency synthesizer 100 can include a reference divider 70 and a post divider 60. According to an embodiment, the reference divider 70 can be designed as a 4 bit programmable divider, the feedback divider 50 can be designed as an 8 bit programmable divider, and the post divider 60 can be designed as a 3 bit programmable divider.

FIG. 2 is a circuit diagram illustrating a PFD 10 according to an embodiment.

Referring to FIG. 2, the PFD 10 can detect a phase difference and a frequency difference between a reference signal f_{R} and a comparison signal f_{S}. When the phase of the comparison signal f_{S} is delayed as compared to the phase of the reference signal f_{R}, the PFD 10 outputs a phase error up signal. However, when the phase of the comparison signal f_{S} is advanced as compared to the phase of the reference signal f_{R}, the PFD 10 outputs a phase error down signal.

According to embodiment, the PFD 10 is constructed such that the PFD 10 can detect frequency as well as phase.

Referring back to FIG. 1, The PFD 10 compares the reference signal f_{R}, which can be an output signal of the reference divider 70, with the comparison signal f_{S}, which can be an output signal of the feedback divider 50, and outputs to the CP 20 the phase error up/down signals corresponding to frequency and phase differences between the two signals.

Referring again to FIG. 2, the PFD 10 can include a delay cell 11 therein such that the PFD 10 minimizes a dead zone phenomenon occurring when the phase error up/down signals simultaneously become high.

The output signal of the PFD 10 can be used to control the CP 20. This can be accomplished by varying a value of a loop filter 23 included in the CP 20.

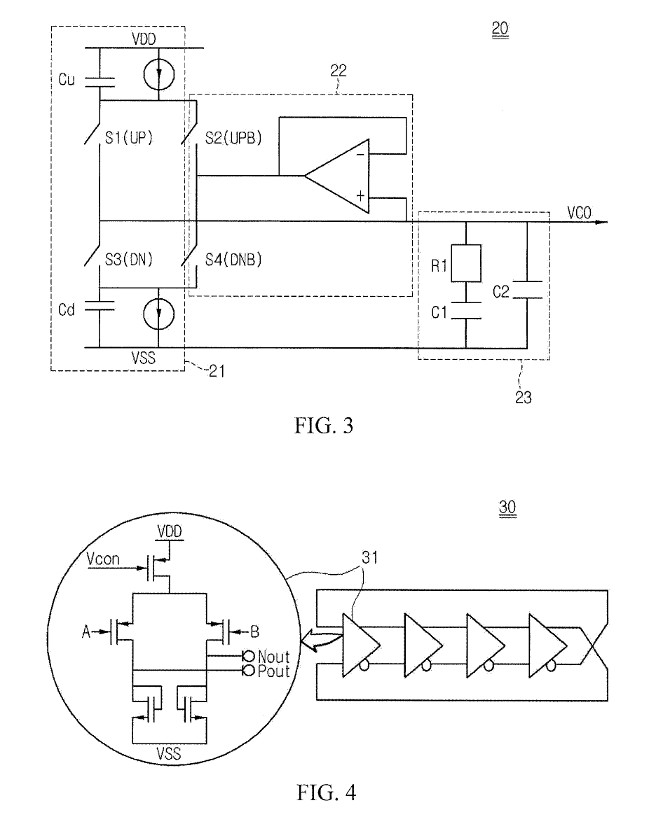

FIG. 3 is a circuit diagram illustrating a CP 20 according to an embodiment.

The CP 20 can include a current source and switching circuit 21, a buffer circuit 22 and a loop filter 23.

The CP 20 charges the loop filter 23 based on the phase error up signal and discharges the loop filter 23 based on the phase error down signal.

The loop filter 23 serves as a low pass filter. In detail, the loop filter 23 allows an output signal having a low frequency band to pass therethrough such that the output signal can be transferred to the VCO 30.

According to an embodiment, the loop filter 23 includes one resistor R1 and two capacitors C1 and C2. The filter parameters are determined in consideration of an open loop band width and a phase margin. In one embodiment, optimal parameters C1, C2 and R1 of the loop filter 23 can be determined by selecting a phase margin of 56° and a loop band width of 1 MHz.

The current source and switching circuit 21 operates based on the phase error up signal and the phase error down signal output from the PFD 10. If the phase error up signal is input to the current source and switching circuit 21, switches S1 and S4 are operated in an on state and switches S2 and S3 are operated in an off state to supply charge current to the loop filter 23.

Further, if the phase error down signal is received from the PFD 10, switches S1 and S4 are operated in an on state and switches S2 and S3 are operated in an off state to allow discharge current to be discharged from the loop filter 23.

The switches S1 and S2 can be PMOS transistors and the switches S3 and S4 can be NMOS transistors.

The loop filter 23 can be charged and discharged by the charge current and the discharge current so that the loop filter 23 generates a control voltage, and provides the control voltage to the VCO 30.

The buffer circuit 22 compensates for switch time mismatch and current mismatch occurring at the VCO 30. Switch time mismatch and current mismatch may occur due to charge sharing generated whenever the PMOS and NMOS transistors are turned on/off by the phase error up/down signals, respectively.

The current mismatch may cause jitter of the frequency synthesizer 100.

Referring to FIG. 3, the buffer circuit 22 includes an OP-AMP. Thus, when switches S1 and S4 are in an off state and switches S2 and S3 are in an on state, the buffer circuit 22 applies a negative charge to capacitor Cu. when switches S1 and S4 are in an on state and switches S2 and S3 are in an off state, the buffer circuit 22 applies a positive charge to capacitor Cd. thereby minimizing the switch time mismatch and the current mismatch.

The loop filter 23 generates the control voltage, at which the VCO 30 oscillates at a target frequency, according to an operation of the CP 20, and outputs the control voltage to the VCO 30.

FIG. 4 is a circuit diagram illustrating a VCO 30 according to the embodiment.

A VCO 30 can be classified as an inverter delay chain type oscillator or a differential delay chain type oscillator. Referring to FIG. 4, according to an embodiment, a differential delay chain type ring oscillator can be used in order to reduce noise of supply voltage.

The ring oscillator can perform an oscillation operation using a current control signal (Vcon). Here, the ring oscillator includes four differential delay cells 31. Thus, the total phase delay is 360°.

The VCO 30 can have a frequency generation range of 500 MHz to 1000 MHz and can process an input signal of 10 MHz to 100 MHz.

The VCO 30 outputs a signal having a frequency controlled by the control voltage. This output signal can be referred to as an oscillation output signal.

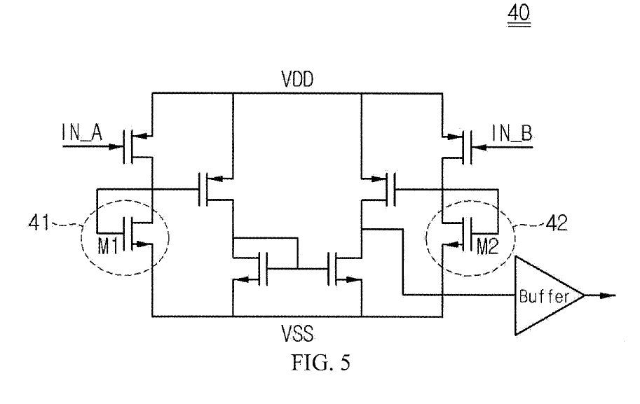

FIG. 5 is a circuit diagram illustrating a DCC 40 according to the embodiment.

The DCC 40 can be added to an output terminal of the VCO 30 such that an output duty cycle ratio of the frequency synthesizer 100 has a value of 50±15%.

The DCC 40 can have a differential structure. The size of widths and lengths of transistors 41 and 42 can be selected such that the frequency synthesizer 100 maintains a duty cycle ratio of 50%.

Referring again to FIG. 1, the feedback divider 50 outputs the comparison signal f_{S} to the PFD 10 by dividing the frequency of the oscillation output signal.

In addition, the frequency synthesizer 100 can further include a power down module 90. The power down module 90 provides a power down mode for reducing power consumption through a switching operation in a standby mode.

In a further embodiment, the frequency synthesizer 100 can include a lock detector 80. In one embodiment, the lock detector 80 can be a 10 bit lock detector for determining a locking state.

The lock detector 80 can be used to determine if the reference signal f_{R}, which is the output signal of the reference divider 70, and the comparison signal f_{S}, which is the output signal of the feedback divider 50, has been locked.

According to one embodiment utilizing a lock detector 80, if the phase difference is smaller than 2 ns during 10 consecutive comparison cycles, the lock detector 80 determines the current state as a locking state and then outputs a high signal. However, if the phase difference is greater than 2 ns during 10 consecutive comparison cycles, the lock detector 80 determines the current state as an unlocking state and then outputs a low signal.

The frequency synthesizer 100 as described above operates such that the comparison signal has the same phase as that of the reference signal, thereby controlling the VCO 30 to oscillate at the target frequency.

Accordingly, embodiments can provide a frequency synthesizer having low jitter components.

In addition, an embodiment can provide a frequency synthesizer capable of minimizing power consumption.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A frequency synthesizer comprising:
a phase frequency detector for generating an up signal and a down signal based on a detected frequency difference and phase difference between a reference signal and a comparison signal;
a charge pump for receiving the up signal and the down signal from the phase frequency detector and outputting a control signal by charging or discharging voltage based on the up signal and the down signal;
a voltage controlled oscillator for outputting an oscillation output signal using the control signal output from the charge pump;
a duty cycle correction circuit connected to the voltage controlled oscillator to compensate for a duty cycle of the oscillation output signal; and
a feedback divider for dividing a frequency of the oscillation output signal and outputting the divided frequency as the comparison signal to the phase frequency detector.

2. The frequency synthesizer according to claim 1, further comprising:
a reference divider for dividing an input frequency and outputting the divided input frequency as the reference signal to the phase frequency detector; and
a post divider for dividing the frequency of the oscillation output signal and outputting the divided frequency of the oscillation output signal.

3. The frequency synthesizer according to claim 2, wherein the reference divider comprises a 4 bit programmable divider.

4. The frequency synthesizer according to claim 2, wherein the post divider comprises a 3 bit programmable divider.

5. The frequency synthesizer according to claim 1, wherein when the phase of the comparison signal is delayed compared to the phase of the reference signal, the phase frequency detector outputs the up signal; and wherein when the phase of the comparison signal is advanced compared to the phase of the reference signal, the phase frequency detector outputs the down signal.

6. The frequency synthesizer according to claim 5, wherein the phase frequency detector comprises a delay cell activated when the up signal and the down signal are both high.

7. The frequency synthesizer according to claim 1, wherein the charge pump comprises:
a current source and switching circuit for controlling charge and discharge operations by performing a switching operation according to the up signal and the down signal of the phase frequency detector;
a loop filter for providing current to the current source and switching circuit when no frequency and phase differences exist between the reference signal and the comparison signal; and
a buffer circuit provided between the current source and switching circuit and the loop filter for compensating for switch time mismatch and current mismatch.

8. The frequency synthesizer according to claim 7, wherein the loop filter comprises a resistor and a first capacitor connected in parallel to a second capacitor.

9. The frequency synthesizer according to claim 1, wherein the voltage controlled oscillator comprises a differential delay chain type ring oscillator.

10. The frequency synthesizer according to claim 9, wherein the voltage controlled oscillator comprises four differential delay cells.

11. The frequency synthesizer according to claim 1, wherein the feedback divider comprises an 8 bit programmable divider.

12. The frequency synthesizer according to claim 1, further comprising a power down for blocking power by a switching operation in a standby mode.

13. The frequency synthesizer according to claim 1, further comprising a lock detector connected with the phase frequency detector to determine a locking state between the reference and comparison signals.

14. The frequency synthesizer according to claim 13, wherein the lock detector comprises a 10 bit lock detector.
